(19) United States
(12) Patent Application Publication
(10) Pub. No.: US 2006/0196414 A1
(43) Pub. Date: Sep. 7, 2006

(54) System for coating a substrate, and an insert element

(75) Inventors: Manfred Schuhmacher, Alzenau (DE); Gerhard Joos, Obernburg (DE)

Correspondence Address: SHERIDAN ROSS PC, 1560 BROADWAY, SUITE 1200, DENVER, CO, 80202, US

(73) Assignee: Applied Films GmbH & Co., KG, Alzenau (DE)

(21) Appl. No.: 11/363,762

(22) Filed: Feb. 27, 2006

(30) Foreign Application Priority Data
Mar. 3, 2005 (EP) 05004725.7
Sep. 28, 2005 (EP) 05021176.2

(51) Int. Cl. C23C 14/00; B05C 5/00; B05B 15/12; B05B 5/025

(52) U.S. Cl. 118/50; 118/50.1; 118/620; 118/300; 118/326

(57) ABSTRACT

A system 1 for coating a substrate 3, in particular a transparent substrate, comprises at least one coating chamber 2, at least one pump means 5 for producing a vacuum within the coating chamber 2, and at least one sputtering cathode 9. One or more cathodes 9 are integrated within an insert 8 together with system components which undergo process-induced dirt pick-up, for example shields, covers or transport rollers 6 for conveying a substrate 3 through the process chamber 2. The insert 8 can slide, like a drawer, through a lateral opening 10 within the chamber wall 2a, into the interior of the chamber. For maintenance purposes, any components of the coating system 1 which require thorough maintenance and cleaning can be removed easily from the interior of the coating chamber 2 by means of the insert 8. The removed insert 8 can be replaced directly by an insert that has just been serviced.

The invention relates to a system for coating a substrate, in particular a transparent substrate, especially for producing architectural glass, comprising at least one coating chamber, and further relates to an insert element for a system for coating a substrate, in particular a transparent substrate.

Glass coating systems for coating large-area substrates, such as large-area architectural glass panes, usually function continuously after the substrates have been locked in one after each other. The substrates are guided through a large number of chambers or chamber segments that are arranged in succession, whereby identical or different treatment and coating processes may run their course within the individual chambers. Pump chambers which prevent contamination between adjacent coating chambers may be positioned there between.

In this kind of system, the installations needed for the process, such as cathodes, anodes, shields, screens, gas supply lines, cooling facilities or the like are attached to flanges, covers or directly to the walls in the interior of the coating chambers. In particular, transport rollers, too, which are provided for continuously conveying the substrate through the coating chamber, are securely fitted within the chamber housing. As regards cathode maintenance, target replacement or the cleaning of components affected by dirt pick-up, the coating chamber can be accessed by detaching a cover that rests at the top on a chamber opening. Access to the interior of the chamber is, however, inconvenient and entails considerable time and effort. The layout of the components secured in the interior of the coating chamber is inconvenient as far as maintenance work is concerned. The components may have to be dismantled in order to perform maintenance work. As a result, long downtimes occur.

In the known continuous coating systems, particularly in the case of systems for large-area substrates, it has, moreover, proved effective to arrange the pump devices adjacent to the coating chambers on the upper side and/or lower side of the pump chambers. The pump device is connected to the detachable cover, with the result that on account of the additional weight, a crane normally has to be used to take off the cover.

Apart from the problem of inconvenient access to those components secured within the coating chamber or attached to flanges, problems arise regarding the sealing of the opening whenever it has to be closed off after completion of maintenance work. This is due to the fact that impurities can be easily deposited on the sealing faces (which are positioned horizontally and are accessible to maintenance personnel). For this reason, once the cover is removed, maintenance staff immediately masks off the sealing faces or covers them up by means of a frame.

On the whole, handling the system during operational shutdown for maintenance purposes is a time-consuming and laborious business. The area that surrounds the cathode and which has been affected by dirt pick-up as a result of the coating process is difficult to access. Whereas it is possible to remove the cathode, the area surrounding the cathode must be cleaned from within the chamber. In particular, the transport rollers secured within the housing and intended for conveying the substrate can, furthermore, be cleaned only with a considerable amount of time and effort. Any particles that have fallen down can only be removed from the chamber with difficulty.

Taking the above as a point of departure, it is the object of the present invention to design a coating system or components of a coating system in such a way that maintenance, cleaning, and target replacement can be simplified and performed in a shorter period of time.

This object is solved by designing a system for coating a substrate as defined in claim 1 and by an insert element as defined in claim 12.

The system for coating a substrate, particularly a transparent substrate, especially for producing architectural glass, comprises at least one coating chamber, and at least one insert element that has coating tools for applying a coating to the substrate, these tools being arranged on the insert element and it being possible to insert these tools, together with the insert element, into the interior of the coating chamber and to retract them therefrom.

The system's insert element or elements may comprise all the characteristics and features described below, especially those features claimed in conjunction with the insert element.

The use of several insert elements within a single facility creates a modular system in which complete cathode stations can be replaced easily by a fully equipped unit. It is thus possible to replace targets more rapidly. This proves to be particularly favourable because the intervals during which target replacement has to be performed may vary from target to target. In principle, there is, in practice, sufficient working space when every second insert is pulled out, thereby enabling work to be performed simultaneously on the retracted inserts. It is, however, possible to carry out work simultaneously on all the insert elements when every second insert is moved to a workstation further away from the system. In principle, a configuration of insert elements on both sides of the chamber is possible, too.

In particular, at least one opening is formed on a lateral wall of the coating chamber such that the insert element can slide into the coating chamber. The disadvantages associated with access from above are avoided by accessing from the side the insert element and the components connected thereto. The manner of sealing the openings of conventional coating chambers, which are closed off by a surface-mounted flange, gives rise to problems caused by the dirt pick-up that affects the horizontal sealing faces. It is necessary to mask off or cover up the sealing faces immediately after they are opened. Access from the side reduces the risk of dirt pick-up, because the sealing faces are not positioned horizontally and since those components which require maintenance are not accessed in the vicinity of these sealing faces. The sealing zones on the lateral insert openings are, moreover, shorter than the sealing zones on the opening within the cover area.

The coating chamber and insert element are preferably adapted to one another in such a way that the insert element can slide like a drawer into the coating-chamber opening.

The system will comprise at least one pump device for producing a vacuum within the coating chamber. The pump device is positioned on the upper side and/or lower side of the chamber housing. An arrangement at the side of a pump box that extends upwards and/or downwards from the coating chamber is particularly beneficial in terms of convenient access. This layout is, nevertheless, only made possible by the idea lying at the heart of the invention, i.e. the provision of the insert element, since it entails a greater degree of flexibility as concerns the pump configuration. The length of the overall system can be reduced because the aforementioned beneficial pump layout makes it possible to dispense with pump chambers between the coating stations.

Regardless of the pump device, the insert element will usually be positioned so as to be movable with respect to the coating chamber. Whereas the pump device is secured to the chamber, it is possible to move the insert element together with any components integrated therein. No covers or pumps need to be moved in order to reach the functional parts attached to the insert.

In particular, the system is designed so that a planar substrate is conveyed in an essentially horizontal fashion through the coating chamber. All the same, the invention is intended to envisage vertical guidance of the substrate, too.

Accordingly, the cathodes integrated within the insert element are preferably aligned horizontally.

In a preferred embodiment, the insert element comprises a terminal for the insert element's voltage supply, this terminal being designed such that whenever the insert element slides into the coating chamber, the terminal engages with a corresponding, system-mounted terminal in order to create the supply connection. Whenever the insert element is retracted from the chamber, contact is automatically broken, thus making it unnecessary for personnel to disconnect the connection manually.

In the interior of the coating chamber there are, in particular, one or more couplings for the purpose of coupling up with the transport rollers attached to the insert element. All that essentially remains inside the chamber are the process-monitoring sensors and the transport-roller couplings. The coating chamber is merely equipped with those components which do not need to be accessed regularly. The chamber itself is a simple sheet-steel housing fitted with insert-element runners and the transport-roller coupling.

The system may comprise a gas control module which is connected to the coating chamber, with the gas control module having at least one gas connection to the inside of the chamber, and the insert element having appropriate gas connections and gas pipes by means of which process gas fed by the gas control module can be guided through the interior of the chamber and via which the process gas can be introduced into the chamber.

The insert element specified by the invention and intended for a system to coat a substrate, especially a transparent substrate, has coating tools for applying a coating to the substrate, which tools are positioned on the insert element and together with the insert element can slide into the interior of a coating chamber or can be retracted therefrom.

Coating tools are particularly intended to be defined here as sputtering sources, sputtering cathodes, magnetrons etc. The invention is, however, intended to include tools in conjunction with other coating techniques, such as vapour deposition of a coating, or the use of an ion source for the substrate's preliminary/subsequent treatment.

The provision of a self-contained unit which can slide into the chamber or which can be retracted therefrom and to which the coating tools are attached facilitates accessibility to these components considerably. On the one hand, no covers or flanges have to be lifted off. On the other hand, the coating tools are available for maintenance purposes as soon as the unit has been pulled out of the coating chamber. In consequence, it is possible to do without an additional expensive cathode conveyance carriage that, moreover, for the purpose of further processing, includes a device for pivoting the cathode around. It is unnecessary to gain access to the interior of the chamber, for instance so as to dismantle the coating tools. What is more, it is possible for a unit that requires maintenance to be replaced quickly and easily by a replacement insert that has already been prepared. Cleaning and maintenance work can be carried out without any time constraints, because the system can start operating with the replacement insert while the work is being performed. This approach simplifies maintenance. System downtimes can be reduced considerably.

Whenever it slides into or is retracted from the coating chamber, the insert element can be moved by means of a lifting unit or jack, on rollers, on an air cushion, on rails or the like.

In particular, the insert element can slide, in the manner of a drawer, into the interior of the coating chamber or it can be retracted therefrom.

Integrated within the insert element are preferably further coating-system components that undergo process-induced wear, dirt pick-up and/or which are exposed to coating material. All these components are therefore easily accessible.

Those components which are positioned in the area surrounding the cathode and which are hit directly or indirectly by coating particles or impurities during the coating process are particularly subjected to process-induced dirt pick-up. Shields, screens, cathode counterwalls and anodes are particularly affected thereby. These components must be cleaned at regular intervals, for example they need to be sand-blasted. Of course, as many components as possible that undergo process-induced dirt pick-up, i.e. which are exposed directly to coating material (or are exposed to scattered particles), should be integrated within the insert element. This makes it possible to dispense with any access to the chamber's interior (for reasons of maintenance). The insert element is used to retract any system components that are intended to be accessible in the course of maintenance. The same goes for wear parts, particularly sputtering cathodes.

The insert element will, furthermore, comprise shields and/or screens. The insert element can be structured in such a way that screens are attached at suitable points in order to prevent the interior of the coating chamber or other components from being affected by dirt pick-up. In this way, no coating material will at any rate reach the space outside the insert element unchecked.

The coating tool may comprise at least one cathode. This may be at least one flat or plane cathode or at least one rotatable cathode. Rotatable cathodes can be integrated into the insert element in a variety of ways. In the preferred embodiment, the tubular target of a rotatable cathode is secured to a rotary vacuum feedthrough positioned parallel to the tubular target's rotary axis in the end-face flange of the insert element. At the opposite end of the insert element, the tubular target is rotatably supported within a mount that is positioned in the region of the rotary-axis extension.

In a further embodiment, commercially available, complete tubular cathodes are resorted to. In this case, the coating tool comprises at least two mounts for holding the cathode. A cathode unit is formed by the mount blocks together with the target, which may particularly be a tubular target, as well as together with the media supply line and cathode drive. The cathode is secured rotatably to the two mount blocks.

In conventional systems, the cathode units are suspended from a cover on the vacuum facility and installed into same. The cathode unit, which is designed as a magnetron, has a magnetic array located inside the tubular cathode. The magnetic array, designed for example as a magnetic strip, must, for operational purposes, be aligned in the sputtering direction, i.e. towards the substrate.

In the present invention, however, the mount blocks are preferably secured in an upright manner to the insert element in accordance with the invention. During coating, the substrates move through between the two mount blocks beneath the cathode tube. Unlike the conventional structure, the cathode unit together with the magnetic array is therefore installed within the insert element during assembly such that the magnetic strip does not face towards the substrate, but faces exactly away from the chamber ceiling. In consequence, only the magnetic strip has to be rotated through 180° in order to install the cathode unit in the insert element, which is immediately possible due to the symmetrically designed attachment members inside the tubular target. To replace the tubular target, the insert element can be retracted from the coating chamber and the target detached from the insert element, without the entire unit comprising the chamber cover, mount blocks and cathode needing to be moved after the supply of media (cooling water, electricity) has been disconnected. In other words, whereas the cover of a conventional system has to be lifted, secured to a special-purpose device and rotated through 180° in order to replace spent targets (install or dismantle targets) after the connection lines have been removed, the inventive cathode unit and the magnet system can remain secured within the insert element in an upright manner on the mount blocks and the target can be removed once the appropriate means of attachment has been disengaged. In this way, not only the maintenance periods, but also the risk of accident during target replacement can be reduced. Furthermore, a device for turning over the cathodes can be dispensed with.

Additionally, in this layout, the media connections can be positioned by means of the mount blocks on the side below the substrate to be coated, i.e. the media lines are guided downwards from the cathode towards underneath the substrate.

The insert element may have a device for rotating the cathode, especially in the case of a flat cathode, into a position which provides access for maintenance purposes and/or for replacing the cathode. This may for example be a crank or a lever, by means of which the flat cathode operated in sputter-down mode can be rotated through approx. 180° after the insert element has been retracted from the coating chamber, thus causing the cathode to point upwards. This makes it convenient for maintenance personnel to access the cathode's screw connection and enables them to replace the target quickly and easily.

In addition, the insert element may have a drive unit or a coupling for a drive unit in order to rotate a rotatable cathode. The drive may be positioned within a section of the insert element that is located outside the chamber. The drive may also be secured outside the chamber at that side which is opposite the insert opening and drive the rotatable cathodes via couplings whenever the system is closed.

Furthermore, it is conceivable to render just the cathodes accessible by means of an insert element on the front of the system, and to locate just the transport rollers or the area surrounding the cathode(s) in a further insert element at the rear. Several individual insert elements that can be operated separately are possible on both sides, too. This could be brought about as a result of two or more individual insert elements which engage with one another. The coating system's individual components, particularly those components which are exposed to process-induced wear or dirt pick-up, can be positioned suitably on the separate insert elements. Not only the claimed insert elements per se are intended to constitute part of the invention, but also the combinations of these insert elements with the further insert elements which, although they do not comprise any cathodes, do bear other coating components.

The insert element may comprise at least one anode. In this case, the anode should at least be a part of the insert element if the anode undergoes dirt pick-up caused by coating material.

The insert element preferably comprises a transport means for the preferably continuous conveyance of the substrate.

The transport means particularly comprises transport rollers which cause the substrate to move. The transport-roller drive may be positioned inside or outside the coating chamber and drive the transport rollers via a coupling. The transport rollers can be screened by protective panels which are likewise part of the insert element.

The insert element may, moreover, comprise a device for cooling the shields, screens and/or coating tools. The insert element is supplied with a cooling medium which is guided via lines to the corresponding components that are to be cooled.

The insert element preferably comprises a flange for sealing off an opening within the coating chamber, this opening being provided for insertion of the insert element.

The insert-element design particularly enables the insert element to travel or slide. For this purpose, rollers or an air cushion etc. can be provided. Auxiliary devices can be used, too, such as a lifting unit or jack, which can engage underneath the insert element and lift it up, or rails on which the insert element can be moved.

The insert element may have supply means for the supply of media. In particular, these are lines for supplying the chamber with gas and/or cooling water for shields and/or the cathodes and/or for supplying it with voltage.

The gas supply is provided for the metering of process gas. The insert element may also particularly comprise control units for regulating the gas supply. The gas supply can be regulated in such a way that the gas is supplied across the entire width of the coating chamber in a uniform or sectional manner. For example, a multi-sectional gas line can be used in order to regulate the inflow of process gas selectively at a specific point in the chamber. The arrangement of the gas-flow control units close to the insert element has the advantage that the gas flow, on account of the short distance to the outlet openings within the chamber, can be varied in a rapid and flexible manner.

In a preferred embodiment, the gas-flow control units are attached to the coating chamber close to the point of separation from the insert element, and they are hence assigned to a specific process chamber. As a result, the insert element can be designed more inexpensively. Separation of the gas connection is shifted to the vacuum chamber so that any leaks affecting the gas line's point of separation cannot take effect on the outside. After the gas-flow control unit, the gas line is almost pressureless, viz. adapted to the process chamber pressure, whereas the gas feed-in lines from the gas supply as far as the gas-flow control unit have a pressure of approx. 3 bar. Separation is therefore effected more easily in the pressureless section of the gas lines, and if there are any leaks, the gas escapes into the process chamber, which is where it is wanted anyway.

In addition, the insert element may comprise connections for the supply of media. Supply and/or disposal connections for supplying gas and/or cooling water to shields and/or cathodes and/or for voltage are provided at an insert-element portion that is always located outside the coating chamber.

The insert element may preferably be designed such that coating tools for coating both sides of the substrate are positioned on both sides of the substrate's transport path. In this instance, the cathodes and screens are positioned essentially symmetrically relative to the planar substrate. Both sides of the substrate are coated at the same time.

In particular, the transport rollers can be positioned such that that side of a substrate which faces towards the rollers can be coated by coating tools arranged on the roller side. Coating in this so-called sputter-up mode entails a specific roller configuration. The distance between the drive axles, which are consecutive in the direction of transportation and which move the transport rollers, must be sufficiently large so that enough material sputtered from the targets placed beneath the substrate can impact the substrate. At the same time, the distance must be set such as to ensure that the substrate is transported reliably while preventing the substrate from sagging.

The transport rollers can, moreover, be screened in such a way that the rollers are prevented from picking up dirt caused by material sputtered directly from the coating tools. Unprotected rollers would be coated just like the substrate. Yet this coating represents roller contamination that causes the surface of the substrate to be subjected to additional stress upon contact with the rollers and may cause this surface to be damaged.

Such screens for the transport rollers on both sides of a through-hole for the film material are designed advantageously without any breaks across the entire system width. If the screens were arranged just around each transport roller and the gaps were left open, these screens would catch the coating material sputtered from the cathode and which would be unable to reach the substrate in these areas. The result would be visible streaks on the glass substrates on account of a considerably varying film thickness when viewed across the width of the substrate.

Since no access to the interior is necessary on a regular basis, the system's operating times can be prolonged. Furthermore, the maintenance personnel's work conditions are improved, system set-up time is reduced considerably and the chamber is prevented from being coated.

Further advantages and features of the present invention will now be explained on the basis of the following description of a preferred exemplary embodiment and on the basis of the attached drawings:

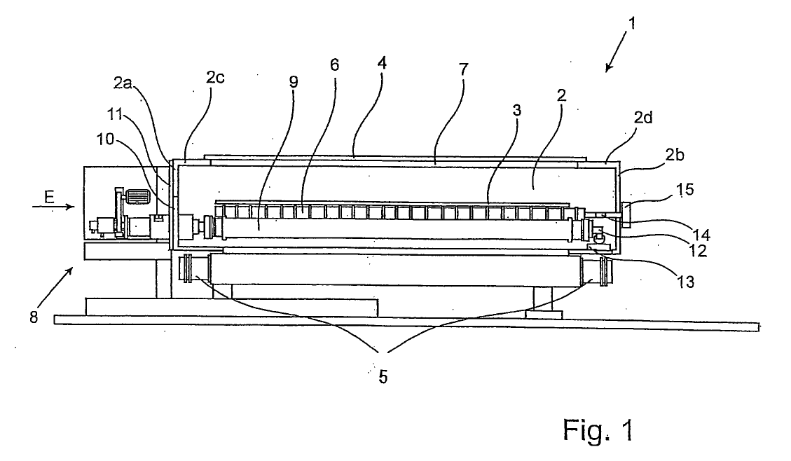

FIG. 1 depicts a sectional view of a coating system in accordance with the invention perpendicular to the substrate's direction of transport;

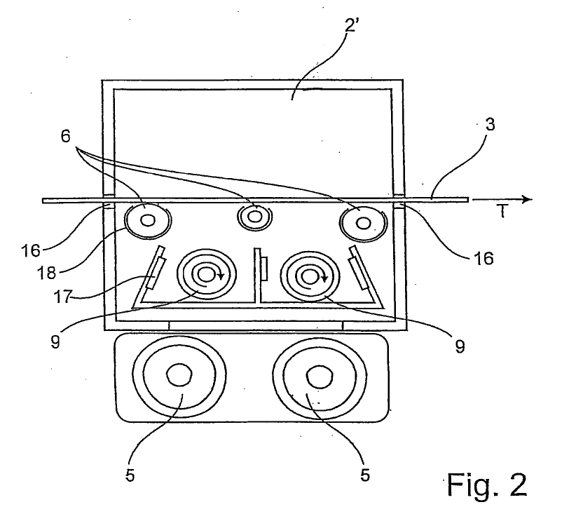

FIG. 2 depicts a further sectional view of a coating system along the substrate's direction of transport;

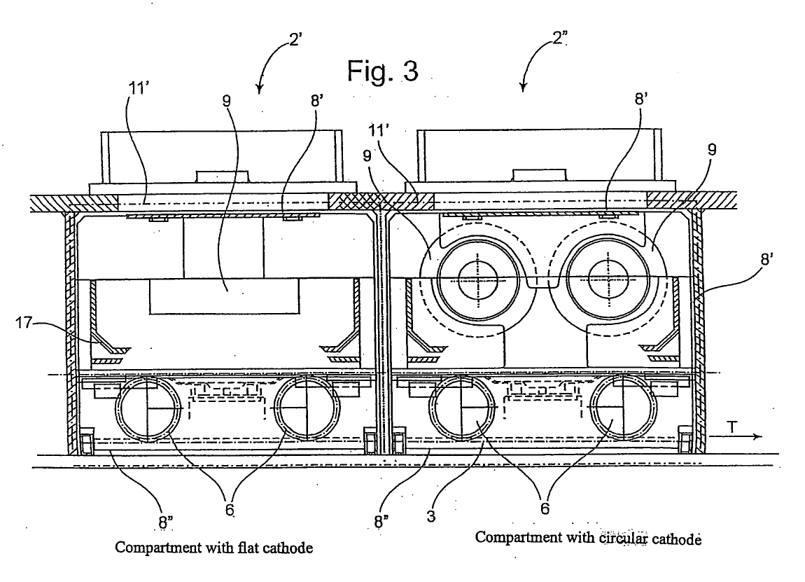

FIG. 3 depicts a sectional view of two chamber segments with inserts in accordance with the invention in a section along the substrate's direction of transport;

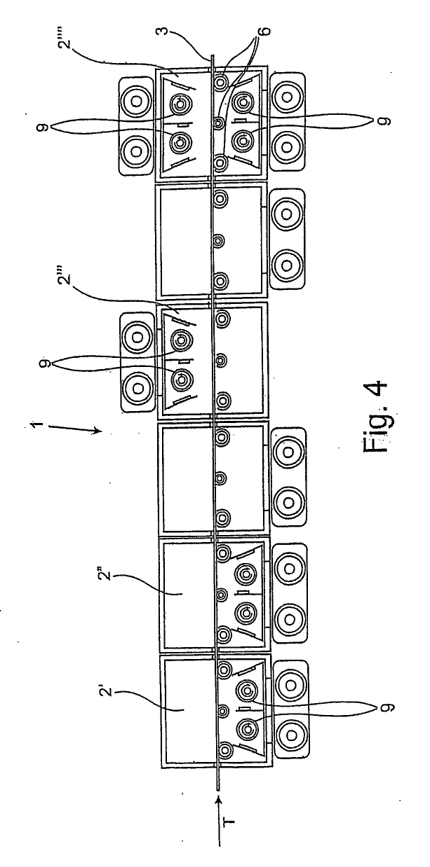

FIG. 4 depicts a sectional view of several chamber segments having variously designed inserts in a section along the substrate's direction of transport;

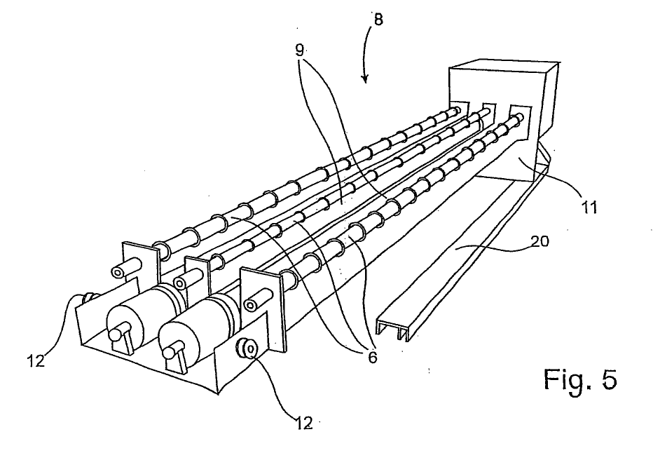

FIG. 5 depicts a perspective view of an insert in accordance with the invention;

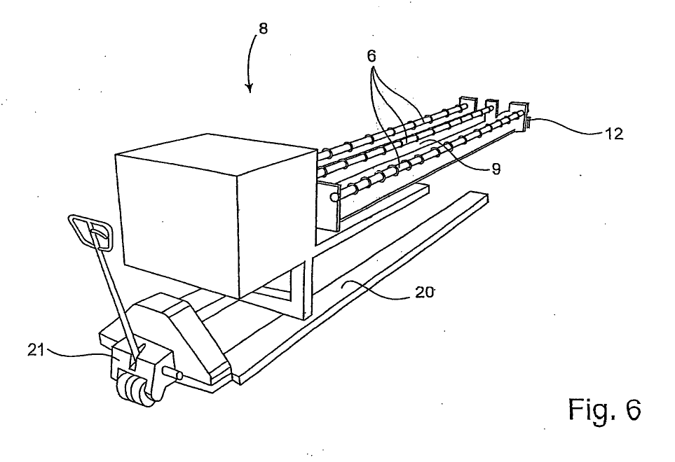

FIG. 6 depicts a further perspective view of an insert in accordance with the invention;

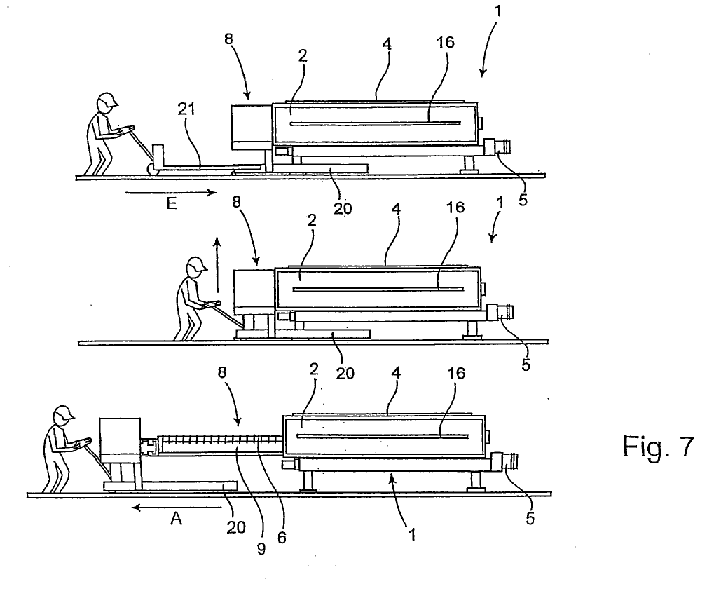

FIG. 7 depicts a schematic representation of insert replacement;

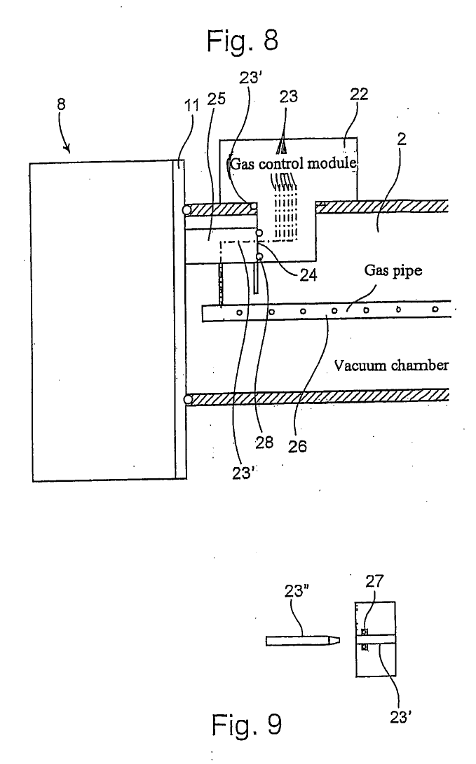

FIG. 8 depicts a representation of a specific embodiment of a gas control module;

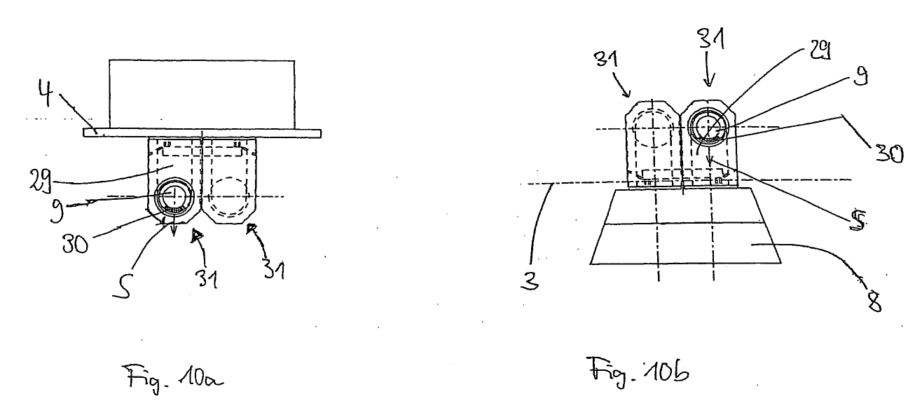

FIG. 9 depicts a detail from FIG. 8;

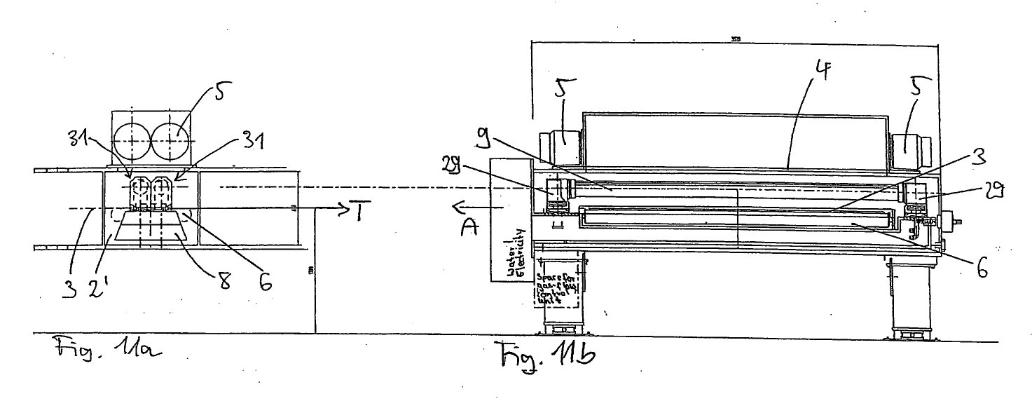

FIG. 10a depicts a cathode unit secured in a conventional manner to a flange;

FIG. 10b depicts a cathode unit secured to an insert element in accordance with the invention;

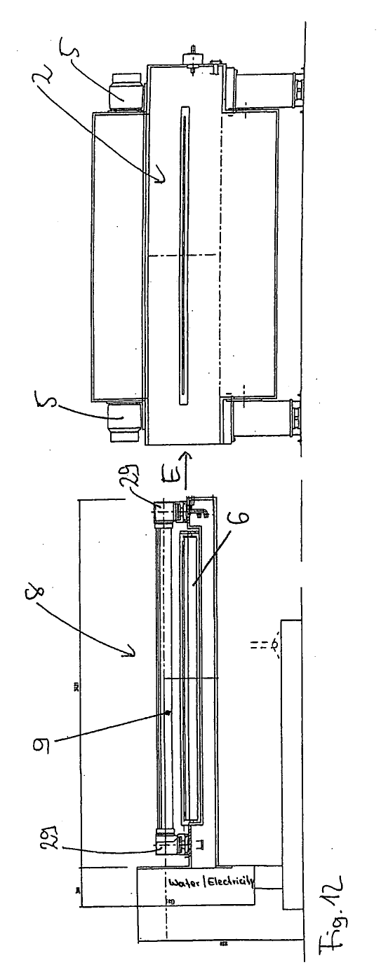

FIG. 11a depicts a coating compartment with a cathode unit in accordance with FIG. 10b as a longitudinal section (relative to the substrate's direction of transport);

FIG. 11b depicts the compartment from FIG. 11a in cross-section (relative to the substrate's direction of transport); and

FIG. 12 depicts a coating chamber having an inventive insert element positioned adjacent thereto.

FIG. 1 depicts a sectional view of a continuously operating glass-coating system 1 comprising a coating chamber 2. The section through the coating system 1 extends perpendicular to the direction of transport of a substrate 3. Within the rough outline of system 1, the substrate 3 is conveyed by rollers 6 in a horizontal position perpendicular to the sheet plane.

The coating chamber 2 is delimited at the sides by lateral walls 2a, 2b. A chamber cover 4, which closes off an opening 7 of the chamber 2, is supported by two flanges 2c, 2d that extend horizontally inwards from the top of the lateral walls 2a and 2b.

In conventional systems, the pump devices are usually located on this cover. At the same time, the opening closed off by the cover represents the only access to the interior of the chamber. Whenever maintenance is to be carried out, the cover must therefore be removed laboriously so as to gain access to the components secured inside the coating chamber or attached to flanges. Access to the chamber's interior, where the components are arranged, is nevertheless inconvenient. Moreover, the dimensions of the opening and the horizontal positioning of the sealing faces causes problems with sealing as a result of impurities that can be easily deposited on the sealing faces.

As is evident from FIG. 1, the pumps 5 (turbomolecular pumps or TMP) in the system 1 according to the invention are arranged essentially in the lateral regions below the coating chamber 2. This arrangement is particularly advantageous for maintenance purposes and for access to the pumps 5. A “sputter-up” technique is employed in the exemplary embodiment. The substrate 3 is positioned horizontally during transport and in the course of the coating process. Coating is performed from bottom up, i.e. the cathode 9 is located below the substrate 3. The situation is reversed in a “sputter-down” mode. The pumps 5 can, however, also be positioned above the chamber 2 without entailing any major drawbacks as a result; it would, furthermore, be conceivable to combine both techniques so as to coat the substrate on both sides, whereby the pumps 5 are arranged symmetrically above and below the chamber 2. Experience has shown that the aforementioned arrangement of the pumps 5 makes it unnecessary to provide pump chambers between every two consecutive coating chambers 2. As a result, the system's structure can be designed to be shorter.

The present invention does, however, hinge on the provision of an insert 8, thus making it largely unnecessary to access the interior of the chamber 2 via the opening 7 for regular maintenance.

The drawer-like insert 8 is a unit made up of various components that are combined within the insert 8. The insert 8 has a vertically aligned, flat flange 11 that seals up a lateral opening 10 in the wall 2a of the coating chamber 2 during operation.

Any components requiring thorough maintenance are secured to the insert 8, for instance the sputtering cathodes 9, which must be replaced at regular intervals, transport rollers 6, which the process causes to pick up dirt, shields, screens and any other components directly or indirectly exposed to the coating material during operation. As many screens and protective panels which prevent the inner walls of the chamber 2 from picking up dirt, such as in the substrate background (i.e. above the substrate 3 in this particular instance), as possible are connected to the insert 8.

Moreover, the entire media supply, e.g. the supply of process gas, cooling water for cathodes and screens, or of voltage, is brought about via lines which are connected to the insert 8.

In the depiction according to FIG. 1, the insert 8 slides, from left to right, like a drawer, into the chamber 2 (insertion direction E) through an opening 10 in the lateral wall 2a until the flange 11 of the insert 8 makes contact with the lateral wall 2a. Evacuating the chamber 2 creates a seal between the flange 11 and the lateral wall 2a. The sealing regions are positioned essentially in a constantly perpendicular manner, consequently do not pick up dirt easily, and are smaller than the sealing regions on the flange 4 on the upper opening 7, i.e. they are easier to clean and handle.

Whenever the insert 8 is introduced into the chamber 2, for example by means of a lifting unit or jack, a roller 12 arranged on the insert 8 cooperates with a guide mechanism 13 on the final section of the route before the operating position is reached so as to adjust the insert 8 correctly. A comparable guide structure can, moreover, be provided in the region of the opening 10 so as to make it easier to slide the insert 8 in and out. Alternatives, such as a guide pin that engages over the final distance, are equally conceivable.

The transport rollers 6 connected to the insert 8 can be connected by means of a coupling 14 to a drive member 15 and driven by same. The coupling 14 transfers for example the rotation of a set of driving gear located outside the chamber 2 to the rollers 6. The transport-roller drive 15 can be designed in a variety of ways. For instance, the drive can be positioned inside or outside the system. If the drive is arranged outside the chamber 2, the drive axle is guided, by means of a rotary vacuum feedthrough, through the lateral chamber wall 2b. Power transmission can be effected via sets of bevel gear, belt drives (toothed belts), gearwheels or the like.

The coupling 14 may be one of the few components or the only component that remains inside the coating chamber 2 when the insert 8 has been pulled out. In addition, it is advisable to mount specific sensors inside the chamber 2 for the purpose of process control, though only if the sensors are not contaminated with coating material during operation.

FIG. 2 shows a vertical sectional view of a chamber segment 2′ having an insert 8 in a section along the direction of transport T of the substrate 3. The substrate 3 is moved through the interior of the chamber segment 2′ by the transport rollers 6 via locks 16. The transport device 6 for the substrate 3 forms part of the insert 8 and is connected thereto. In this embodiment, moreover, the insert 8 comprises two rotatable cathodes 9, shields or anodes 17 and additional screens 18 for the transport rollers. For maintenance purposes, therefore, the aforementioned components can be retracted, together with the insert 8, from the interior of the coating chamber 2.

In this embodiment, the screen faces (here the shields 17) are designed as an open trapezium (trapezoid) and also assume the function of the anodes. In the space behind the cathodes 9, the screens, which are positioned horizontally during operation, may have breaks through which any gas present inside the chamber passes to reach the high-vacuum pumps 5.

It is also apparent from FIG. 2 that the substrate 3 can be coated from below by means of the cathodes 9 arranged under the substrate 3. The transport rollers 6 are, with respect to the substrate, arranged on the same side as the cathodes 9, viz. below the substrate 3. To achieve effective coating of the substrate 3 in this “sputter-up” mode, a distance between the transport rollers 6 must be provided in the direction of transport such that sufficient sputtered coating material can impact the substrate 3 without interfering with substrate transportation.

The transport rollers 6 must also be protected by way of a screen 18 at least from exposure to any particles coming directly from the cathodes 9. Otherwise the transport rollers 6 would themselves be coated and accumulate so much dirt over time that the transport rollers 6 would be expected to cause damage to the substrate 3 or to the coating of the substrate 3.

FIG. 3 depicts two chamber segments 2′, 2″ each with inserts 8 in a vertical sectional view along the substrate's direction of transport T. The segments 2′, 2″ are intended for the “sputter-down” technique. Each substrate 3 is guided through the chamber segments 2′, 2″ by means of two transport rollers 6.

The first insert 8 (shown on the left) has a flat cathode 9, while the second insert 8 (shown on the right) has two rotatable circular cathodes 9. The sputtering cathodes 9 may generally be magnetrons as well. Furthermore, it would be conceivable to apply the core idea of the invention to other coating techniques, such as vapour deposition (PVD, CVD). The coating tools required for the specific process are in any case integrated within the insert 8 so as to permit simple replacement and maintenance.

The drive for the circular cathodes 9 is integrated within the external section of the insert 8. The insert 8 for the flat cathode 9 has a lever (not depicted) with which the flat cathode 9 can be rotated through approx. 180° so as to be removed.

The outer contours of the flange 11 are designated by reference number 11′ and indicated by broken lines; the outer contours of the inserts 8 are designated by reference numbers 8′, 8″ and indicated by continuous lines. Shields 17, which simultaneously serve as anodes, and other screens protect the inside of the walls of the coating chamber 2 from being impacted by coating material. The screen panel 8″ in the background of the substrate 3 (relative to the cathodes 9) has the same function, whereby this screen panel 8″ forms part of the insert 8, too. A cooling unit (not depicted) is provided in a region of the shield 17. A further cooling unit for the cathodes 9 is likewise integrated within the insert 8.

FIG. 3 depicts just two inserts 8. Normally, however, a series of consecutive chamber segments 2′, 2″, 2′″, . . . with corresponding inserts 8 will be provided in a glass-coating system 1, as shown in FIG. 4.

Identical or different treatment and/or coating processes can run their course in the chamber segments 2′, 2″, 2′″, . . . . The segments 2′, 2″, 2′″, . . . are separated from each other by means of slot-type locks that are placed on the front and rear walls of the chamber segments 2′, 2″, 2′″, . . . so that the substrate 3 can be passed through. The substrates 3 are transported from one chamber segment to the next one by means of the through the locks.

While the chamber segments 2′, 2″ are set up for the “sputter-up” mode, “sputter-down” takes place in the segment 2′″. The segment 2“ ” is where the upper and lower sides of the substrate are simultaneously coated. The insert 8 for this chamber segment 2“ ” is therefore designed to be essentially symmetrical to the transport plane of the substrate 3, having two rotating cathodes 9 respectively on both sides of the substrate and mirror-symmetrical shield arrays 17. A total of three transport rollers 6 for conveying the substrate 3 through the segment 2″″ have a simple design. If the substrate 3 is coated on both sides, pumps 5 are provided both on the cover and on the base section of the corresponding chamber segment 2″″. The high-vacuum pumps (TMPs) are screwed to the system 1 and can be detached irrespective of the system 1's remaining components.

A pump chamber is interposed between the segments 2″ and 2′″, although this chamber can usually be dispensed with if the pumps 5 are configured in the manner depicted in conjunction with this invention.

FIGS. 5 and 6 depict perspective views of an insert 8 as specified by this invention and which has been retracted from the coating chamber 2, the reference numbers for the individual components being those used previously.

In this example, a base member 20 of the insert 8 is designed in such a way that a lifting unit 21 can engage and the insert 8 is convenient to transport.

FIG. 7 is a schematic representation of insert replacement. From the side, the operator moves a lifting unit 21 up to the system 1. The lifting unit is moved in insertion direction E and engages with the designated base member 20 of the insert 8. The insert 8 is then lifted and pulled out of the coating chamber 2 in retraction direction A.

Alternatively, the insert 8 can be moved on rollers, an air cushion, rails etc.

The components of the insert 8 can now be accessed conveniently for maintenance there and then or they can be replaced with a prepared replacement insert. The insert 8 that was removed from the chamber 2 can be taken away on rails if circumstances require, while the second, newly equipped and serviced insert 8 can be moved, from the other side, up to the lateral opening 10 of the coating chamber 2 and inserted into the empty chamber segment 2′.

The inserts 8 can be retracted completely from the coating chamber 2. It is consequently no longer necessary to access the coating chamber 2 in order to maintain or clean built-in components. Not only does this approach simplify maintenance, it can also greatly reduce the downtimes of the system 1. Any components subject to process-induced dirt pick-up are located within the insert 8 or form part of the insert 8. Furthermore, cleaning and maintenance can be carried out without time constraints if the system starts operating again with the replacement insert 8 while maintenance work is being performed. As a whole, this approach saves time and money as far as operating the glass-coating system 1 is concerned.

FIG. 8 depicts a special embodiment of a gas control module 22 connected to the coating chamber 2. The gas control module 22 is secured to the coating chamber 2 and comprises a plurality of individual gas-flow control units. As a result, the insert element can be designed more inexpensively. Gas lines 23 lead into the interior of the chamber 2. The gas lines 23 are combined into a single gas line 23′ in the component projecting down into the chamber. This gas line 23′ terminates at a separating point 24 where it merges into the line 23″ that is integrated within the component 25. The component 25 forms part of the insert 8, i.e. it can, together with the insert, be retracted from the chamber 2. The gas line 23″ merges into a gas pipe 26. Openings (shown as circles) are arranged within the gas pipe 26; it is through these openings that the process gas supplied via the gas-control module 22 reaches the vacuum chamber. The connection between the lines 23′ and 23″ at the separating point 24 is brought about, for example, by introducing a pipe (gas line 23″) into a bore (this pipe forming the gas line 23′), as shown in the detail sketch in FIG. 9.

The pipe 23′ can be sealed with respect to the bore 23′ by means of one or more sealing rings 27. Likewise, in order to seal up the transition, a sealing ring 28 can be placed at the separating point 24 so as to separate the section on the insert side from the section on the chamber side.

In this way, the separation 24 of the gas connection(s) is shifted to the vacuum chamber, thus preventing any leaks at the gas line's point of separation from taking effect on the outside. The connection region 24 is located within the process chamber 2 under process chamber pressure, whereas the gas feed-in lines from the gas supply as far as the gas-flow control unit have a pressure of approx. 3 bar.

FIGS. 10a and 10b depict a special embodiment of the coating tools 9. A cathode unit 31 is formed by tubular cathodes or tubular targets together with two mount blocks 29 in each case, with the tubular cathodes being attached to the ends of these blocks. These figures each depict two cathode units 31 side by side.

FIG. 10a shows a case that is familiar from the prior art and in which the cathode units 31 are attached to a cover flange 4, for instance suspended from a chamber cover. The cathodes, which are designed as magnetron cathodes, have a magnetic strip 30 that is provided to create the magnetic field aligned towards a substrate 3. The magnetic strip 30 is arranged within the lower region of the tubular target and is aligned towards the substrate 3, i.e. downwards. The sputtering direction S therefore extends down towards the substrate 3.

If such commercially available cathode units are to be used, the cathode units 31 must, as shown in FIG. 10b, therefore be arranged on the insert element 8 in the manner specified by the invention. The mount blocks 29 are detachably secured to the insert element 8 in an upright manner. During coating mode, the substrates 3 move through between the mount blocks 29 underneath the cathode tube. Right during installation into the tubular cathode, the magnetic strip 30 is aligned downwards in sputtering direction S and in the direction of the substrate 3 that is passed through between the mount blocks 29 beneath the cathode 9. To detach the target, the insert element 8 can be pulled out of the coating chamber 2 and the target can be taken off from the insert element 8. The overall layout facilitates both installation and removal of the magnetic system from the cathode.

FIG. 11a depicts a corresponding configuration in which the cathode unit 31 is placed on an insert element 8 as specified by this invention. T indicates the substrate's direction of transport and plane of transport. As shown in FIG. 11b as well, an inlet chamber with turbomolecular pumps 5 laterally arranged thereon is located within the chamber cover 4 above the coating chamber 2. The substrate 3 advantageously moves through the chamber segment on transport rollers 6 below the cathode 9. In this embodiment, as already described in conjunction with FIG. 10b, the magnetic strip within the magnetic tube must be positioned in the lower section of the tubular cathode 9 right during installation and removal.

As is evident from FIG. 11b, media connections can be guided down through the mount blocks 29, which support the ends of the cathode 9. In this way, the supply lines for the requisite media can run beneath the substrate.

FIG. 12 shows a coating chamber 2 and, next to same, an insert element 8 that has been pulled out of the coating chamber 2 (insertion direction E) and which has transport rollers 6, a tubular cathode 9, and mount blocks 29 arranged at the ends of the tubular cathode 9 and which, together with the cathode 9, form a cathode unit 31. The mount blocks are secured detachably in an upright manner on the insert element 8. During operation, a substrate is transported through between the mount blocks 29 beneath the cathode. The cathode unit also comprises media connections on the underside of the mount blocks 29.

### List of Reference Numbers

1 Glass-coating system
2 Coating chamber
2′, 2″, 2′″, . . . Chamber segments
2a, 2b Lateral walls of the coating chamber
2c, 2d Flanges
3 Substrate
4 Chamber cover
5 Pumps (TMP)
6 Transport rollers
7 Chamber's upper opening
8 Insert
8′ Outer contour of insert 8
8″ Rear wall of insert 8
9 Cathode
10 Lateral opening within chamber wall
11 Flange
11′ Outer contour of flange 11
12 Roller
13 Guide mechanism
14 Coupling
15 Drive member
16 Locks
17 Shield, anode
18 Screen
19 Cooling unit
20 Base member
21 Lifting unit
22 Gas control module
23, 23′, 23″ Gas lines
24 Separating point
25 Component of insert 8
26 Gas pipe
27 Sealing ring
28 Sealing ring
29 Mount block
30 Magnetic strip
31 Cathode unit
E Direction of insertion
A Direction of retraction
T Substrate's direction of transport
S Sputtering direction

1. A system for coating a substrate, in particular a transparent substrate, especially for producing architectural glass, comprising:
at least one coating chamber; and
at least one insert element that has coating tools for applying a coating to said substrate, said tools being arranged at said insert element, said tools, together with said insert element, being insertable into the interior of said coating chamber or being retractable therefrom.

2. A system in accordance with claim 1, wherein at least one opening on a lateral wall of said coating chamber is designed such that said insert element can be inserted into said coating chamber.

3. A system in accordance with claim 2, wherein said coating chamber and said insert element are adapted to one another such that said insert element can be inserted like a drawer into the opening of said coating chamber.

4. A system in accordance with claim 1, wherein said system comprises at least one pump means for producing a vacuum within said coating chamber.

5. A system in accordance with claim 4, wherein said insert element is arranged movably with respect to said coating chamber irrespective of said pump means.

6. A system in accordance with claim 1, wherein said system is designed such that a planar substrate is transported essentially horizontally through said coating chamber.

7. A system in accordance with claim 1, wherein said cathodes are aligned horizontally.

8. A system in accordance with claim 1, wherein said insert element comprises a terminal for supplying said insert element with voltage, said terminal being designed such that when said insert element is inserted into said coating chamber, said terminal engages with a matching terminal arranged on said system so as to establish a supply connection.

9. A system in accordance with claim 1, wherein said coating chamber comprises at least one coupling in the interior of said chamber so as to couple up with transport rollers of said insert element.

10. A system in accordance with claim 1, wherein said coating chamber comprises at least one coupling in the interior of said chamber so as to couple up with the rotatable cathodes and to drive said cathodes whenever the system is closed.

11. A system in accordance with claim 1, wherein said system comprises a gas control module connected to said coating chamber, said gas control module having at least one gas connection to the interior of said chamber, and said insert element comprises corresponding gas connections and gas lines through which any process gas supplied by said gas control module is passed through the interior of said chamber and via which the process gas is introduced into said chamber.

12. An insert element for a system for coating a substrate, in particular a transparent substrate, comprising:
coating tools for applying a coating to said substrate, said tools being arranged on said insert element and said tools, together with said insert element, being insertable into the interior of a coating chamber or being retractable therefrom.

13. An insert element in accordance with claim 12, wherein said insert element can be inserted like a drawer into the interior of said coating chamber or can be retracted therefrom.

14. An insert element in accordance with claim 12, wherein further coating-system components that undergo process-induced wear or dirt pick-up and/or that are exposed to coating material are integrated inside said insert element.

15. An insert element in accordance with claim 12, wherein said insert element comprises at least one of shields and screens.

16. An insert element in accordance with claim 12, wherein said coating tool comprises at least one cathode.

17. An insert element in accordance with claim 16, wherein said coating tool comprises a cathode unit having at least two mounts for holding said cathode, in particular a tubular target.

18. An insert element in accordance with claim 17, wherein said mounts are arranged in an upright manner on said insert element.

19. An insert element in accordance with claim 17, wherein said mounts are arranged parallel to the axis of the tubular target.

20. An insert element in accordance with claim 12, wherein said coating tool comprises at least one flat cathode.

21. An insert element in accordance with claim 20, wherein said insert element comprises a means for rotating said cathode into a position that permits access for maintenance purposes and/or for target replacement.

22. An insert element in accordance with claim 12, wherein said coating tool comprises at least one rotatable cathode.

23. An insert element in accordance with claim 22, wherein said insert element comprises a drive unit or a coupling for a drive unit to rotate said cathode.

24. An insert element in accordance with claim 12, wherein said insert element comprises at least one anode.

25. An insert element in accordance with claim 12, wherein said insert element comprises a transport means for the preferably continuous conveyance of said substrate.

26. An insert element in accordance with claim 25, wherein said transport means comprises transport rollers that move said substrate.

27. An insert element in accordance with claim 12, wherein said insert element comprises a means for cooling at least one of said shields, screens and coating tools.

28. An insert element in accordance with claim 12, wherein said insert element comprises a flange for sealing up an opening in said coating chamber, said opening being intended for the insertion of said insert element.

29. An insert element in accordance with claim 12, wherein said insert element is designed to move or slide.

30. An insert element in accordance with claim 12, wherein said insert element comprises supply means for the provision of media.

31. An insert element in accordance with claim 12, wherein said insert element comprises connections for the provision of media.

32. An insert element in accordance with claim 12, wherein said insert element comprises control units for regulating the supply of process gas.

33. An insert element in accordance with claim 12, wherein said insert element is designed such that coating tools for coating both sides of said substrate are placed on both sides of the transport path of said substrate.

34. An insert element in accordance with claim 26, wherein said transport rollers are arranged such that that side of a substrate which faces said rollers can be coated by means of coating tools positioned at the roller side.

35. An insert element in accordance with claim 34, wherein said transport rollers comprise a screen such that said rollers are prevented from picking up dirt as a result of material sputtered directly by said coating tools.

36. An insert element in accordance with claim 35, wherein said screen for said transport rollers extends across the entire coating width of the substrates and covers a plurality of transport rollers.
